(19) United States
(12) Patent Application Publication
(10) Pub. No.: US 2026/0136694 A1
(43) Pub. Date: May 14, 2026

(54) IMAGE SENSING DEVICE

(71) Applicant: SK hynix Inc., Icheon-si (KR)

(72) Inventor: Woo Yung JUNG, Icheon-si (KR)

(21) Appl. No.: 19/281,423

(22) Filed: Jul. 25, 2025

(30) Foreign Application Priority Data
Nov. 13, 2024 (KR) 10-2024-0161395

(51) Int. Cl. H10F 39/00

(52) U.S. Cl. CPC H10F 39/8063; H10F 39/8053

(57) ABSTRACT

Image sensing devices are disclosed. In an embodiment, an image sensing device includes a semiconductor substrate including photoelectric conversion elements configured to generate photocharges by converting incident light; and a metalens layer disposed over the semiconductor substrate, and configured to separate incident light into light components of different colors based on wavelength and to converge the separated light components onto corresponding photoelectric conversion elements. The metalens layer may include: a first metalens layer including first nano-structures and a first air layer disposed between the first nano-structures; a second metalens layer including second nano-structures and a second air layer disposed between the second nano-structures, wherein at least a portion of each of the second nano-structures is disposed on a corresponding first nano structure of the first nano structures; and a support layer disposed over the first air layer in a space between adjacent first nano-structures of the first nano-structures.

### CROSS-REFERENCE TO RELATED APPLICATION

This patent document claims the priority and benefits of Korean patent application No. 10-2024-0161395, filed on Nov. 13, 2024, which is incorporated by reference in its entirety as part of the disclosure of this patent document.

### TECHNICAL FIELD

The technology and implementations disclosed in this patent document generally relate to an image sensing device including one or more metalenses.

### BACKGROUND

Meta-optics refers to a field of optical technology that enables novel optical properties that cannot be achieved with conventional materials, by utilizing nanostructures smaller than the wavelength of light.

An image sensor is a device that converts an optical image into an electrical signal. Each pixel of the image sensor includes microlenses and color filters. As the demand for high-resolution cameras increases, pixel sizes are becoming miniaturized. As a result, the sizes of the microlenses and color filters in the pixels also decreases, resulting in a decrease in optical efficiency.

To overcome such limitations, active research is underway on metalenses based on meta-optics that can be applied to image sensors.

### SUMMARY

Various embodiments of the disclosed technology relate to an image sensing device capable of ameliorating degradation of quantum efficiency (QE) due to oblique incident light.

In an embodiment of the disclosed technology, an image sensing device may include a semiconductor substrate including photoelectric conversion elements configured to generate photocharges by converting incident light; and a metalens layer disposed over the semiconductor substrate, and configured to separate incident light into light components of different colors based on wavelength and to converge the separated light components onto corresponding photoelectric conversion elements. The metalens layer may include: a first metalens layer including first nano-structures and a first air layer disposed between the first nano-structures; a second metalens layer including second nano-structures and a second air layer disposed between the second nano-structures, wherein at least a portion of each of the second nano-structures is disposed on a corresponding first nano structure of the first nano structures; and a support layer disposed over the first air layer in a space between adjacent first nano-structures of the first nano-structures.

In another embodiment of the disclosed technology, an image sensing device may include a semiconductor substrate including photoelectric conversion elements configured to generate photocharges by converting incident light; a plurality of first nano-structures disposed over the semiconductor substrate; a first air layer disposed between adjacent first nano-structures of the plurality of first nano-structures; a support layer disposed between the first nano-structures such that at least a portion of the adjacent first nano-structures are exposed; a plurality of second nano-structures disposed over the first nano-structures; and a second air layer disposed between the second nano-structures.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some embodiments of the disclosed technology.

FIG. 2 is a schematic diagram illustrating an example structure of a metalens layer formed in a central portion of a pixel region shown in FIG. 1 based on some embodiments of the disclosed technology.

FIG. 3 is a schematic diagram illustrating an example structure of a metalens layer formed in an edge portion in the pixel region shown in FIG. 1 based on some embodiments of the disclosed technology.

FIGS. 4 to 14 are cross-sectional views illustrating example methods for forming the structure of FIG. 2 based on some embodiments of the disclosed technology.

### DETAILED DESCRIPTION

This patent document provides implementations and examples of an image sensing device including one or more metalenses that may be used to substantially address one or more technical or engineering issues and mitigate limitations or disadvantages encountered in some other image sensing devices. Some implementations of the disclosed technology provide examples of image sensing devices designed to ameliorate the degradation of quantum efficiency (QE) caused by oblique incident light. In recognition of the issues above, the disclosed technology provides various implementations of the image sensing device that can ameliorate the degradation of quantum efficiency (QE) with respect to oblique incident light incident on the image sensing device to which metalenses are applied.

The following description refers in detail to certain embodiments, examples of which are illustrated in the accompanying drawings. Wherever possible, like reference numerals and characters are used throughout the accompanying drawings to refer to like components. In the following description, a detailed description of related known configurations or functions will be omitted to avoid obscuring the subject matter.

Hereinafter, various embodiments will be described with reference to the accompanying drawings. However, it should be understood that the disclosed technology is not limited to specific embodiments, but encompasses various modifications, equivalents and alternatives of the embodiments. The embodiments of the disclosed technology may provide a variety of effects capable of being directly or indirectly recognized through the present disclosure.

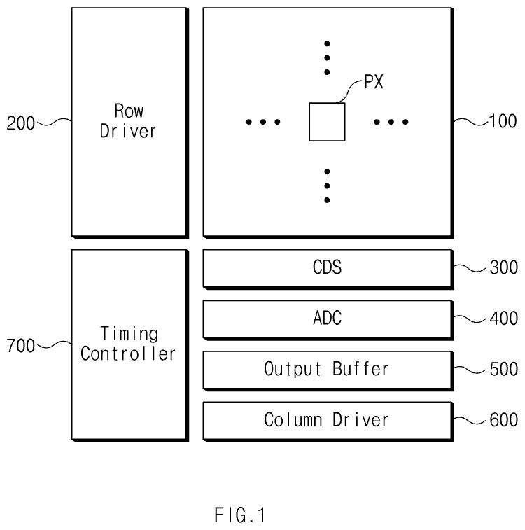

FIG. 1 is a block diagram illustrating an example of an image sensing device based on some embodiments of the disclosed technology.

Referring to FIG. 1, the image sensing device may include a pixel region 100, a row driver 200, a correlated double sampler (CDS) 300, an analog-to-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel region 100 may include a plurality of unit pixels (PXs) arranged in a two-dimensional (2D) structure including rows and columns. The unit pixels (PXs) may convert incident light into a corresponding electrical signal to generate a pixel signal and output the pixel signal to the correlated double sampler (CDS) 300 through column lines. The pixel region 100 may include a metalens that serves as a color router for visible light. In the metalens, an air layer may be formed between adjacent nano-posts, and the nano-posts may be formed in a multilayer structure to prevent deterioration of luminous efficiency caused by oblique incident light.

The pixel array 100 may receive driving signals (for example, a row selection signal, a reset signal, a transfer signal, etc.) from the row driver 200. Upon receiving the driving signals, the unit pixels may be activated to perform the operations corresponding to the row selection signal, the reset signal, and the transfer signal.

The row driver 200 may activate the unit pixels based on control signals received from controller circuitry such as the timing controller 700.

The correlated double sampler (CDS) 300 may remove undesired offset values of the unit pixels using correlated double sampling.

The ADC 400 may convert the CDS signal received from the correlated double sampler (CDS) 300 into a digital signal.

The output buffer 500 may temporarily store column-based data received from the ADC 400 under the control of the timing controller 700.

The column driver 600 may select a column of the output buffer 500 under the control of the timing controller 700, and may sequentially output data temporarily stored in the selected column of the output buffer 500.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column.

In some embodiments, as explained above, the metalens may function as a color router by spatially separating incident visible light based on its wavelength. This enables the metalens to direct different color components (e.g., red, green, and blue) toward corresponding photoelectric conversion elements. In some implementations, the metalens can replace the color filter array. In some embodiments, this color routing functionality is achieved through a structure including a plurality of nano-posts (or nano-pillars) arranged in a certain pattern. In some implementations, by adjusting height, diameter, and/or material composition of the nano-posts, the metalens can control the propagation direction of different wavelengths.

A metalens utilizes a phase difference between high-refractive-index materials (e.g., nano posts) and low-refractive-index materials (e.g., air) to focus specific wavelengths of light onto corresponding photoelectric conversion elements or color filters, thereby maximizing the refractive index difference and enabling reduced metalens height. In some implementations, light is incident at oblique angles, but physically tilting nano posts is impractical.

To address this issue, the disclosed technology can be implemented in some embodiments to provide a metalens structure in which nano posts are formed in vertically stacked layers, with each layer laterally shifted relative to the layer below it. In some implementations where upper nano posts are disposed on lower nano posts, an oxide layer is formed between the upper nano posts and the lower nano posts for structural support, a support layer (e.g., oxide layer) is formed between the upper and lower nano posts.

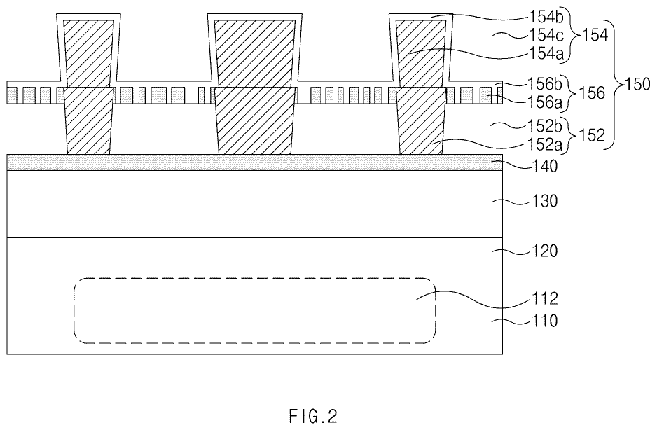

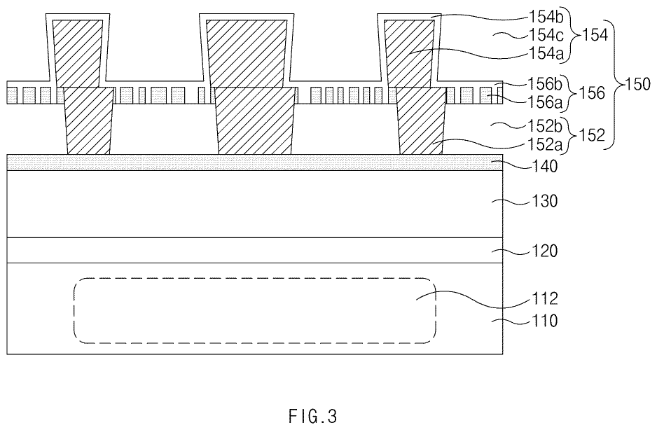

FIG. 2 is a schematic diagram illustrating an example structure of a metalens layer formed in a central portion of the pixel region shown in FIG. 1 based on some embodiments of the disclosed technology. FIG. 3 is a schematic diagram illustrating an example structure of a metalens layer formed in an edge portion in the pixel region shown in FIG. 1 based on some embodiments of the disclosed technology.

Referring to FIGS. 2 and 3, the image sensing device may include a substrate layer 110, a color filter layer 120, an overcoating layer 130, an etch stop layer 140, and a metalens layer 150.

The substrate layer 110 may include a semiconductor substrate having a first surface and a second surface opposite to the first surface. From the perspective inside the semiconductor substrate, the first surface and the second surface face each other. In some implementations, the first surface is a surface upon which light is incident, and the color filter layer 120, the overcoating layer 130, the etch stop layer 140, and the metalens layer 150 may be formed thereon. The semiconductor substrate may be in a monocrystalline state, and may include a silicon-containing material. That is, the semiconductor substrate may include a monocrystalline silicon-containing material. The semiconductor substrate may include the photoelectric conversion elements 112 that can convert incident light received through the first surface of the semiconductor substrate into photocharges.

The color filter layer 120 may include a plurality of color filters arranged to respectively correspond to the unit pixels. The color filters may be arranged in a Bayer pattern. The color filter layer 120 may include a grid structure disposed between the color filters to prevent crosstalk between the color filters.

The overcoating layer 130 may be disposed over the color filter layer 120, and may operate as a planarization layer to remove a height difference between the grid structure and the color filters. The overcoating layer 130 may include a material that is transparent to visible light, for example, a dielectric material (e.g., SiO₂, siloxane-based spin on glass (SOG), etc.) that has a lower refractive index than nanostructures (nano-posts) of the metalens layer 150 and a low absorption rate in the visible spectrum. The overcoating layer 130 may include a material and thickness that can achieve a target refractive index together with the etch stop layer 140. The target refractive index may be a theoretical refractive index designed for the effective medium disposed between two materials, so that a light reflectivity occurring at an interface between materials with different refractive indices can be minimized.

The etch stop layer 140 may be formed over the overcoating layer 130 and may serve as an etch stop to protect the overcoating layer 130 during the etching process for forming one or more first nano-posts 152a. The etch stop layer 140 may include an ultra-low-temperature oxide (ULTO) layer.

A metalens layer 150 may converge (focus) incident light onto the photoelectric conversion elements 112 of the substrate layer 110. For example, the metalens layer 150 may separate incident light into light beams (or light components) of different colors corresponding to color filters arranged in a Bayer pattern, and may focus the separated light onto the photoelectric conversion elements 112 of the corresponding unit pixel. Since diffraction or scattering characteristics of light differ depending on wavelengths of light, the metalens layer 150 may use such characteristics to separate the colors of incident light from each other. The transmission direction of the separated light beam may be adjusted in correspondence with each wavelength according to the refractive index distribution of the metalens layer 150 and the shape of the nano-posts.

The metalens layer 150 may include a first metalens layer 152, a second metalens layer 154, and a support layer 156.

The first metalens layer 152 may include first nano-posts 152a and an air layer 152b, and the second metalens layer 154 may include second nano-posts 154a, a capping layer 154b, and an air layer 154c.

Each of the first nano-posts 152a and each of the second nano-posts 154a may be formed in a pillar shape with a diameter smaller than a wavelength of incident light. For example, the nano-posts (152a, 154a) may be formed in various pillar shapes such as pillar shapes with a cylindrical cross-section, a polygonal cross-section, and an elliptical cross-section. The air layer 152b may be formed between the first nano-posts 152a, and the air layer 154c may be formed between the second nano-posts 154a.

The first nano-posts 152a and the second nano-posts 154a may be formed of the same material, and may be stacked in a one-to-one correspondence to form a nano-structure of the metalens layer 150. For example, the nano-posts (152a, 154a) may include a high-refractive-index material (e.g., TiO₂), and may be stacked with each other such that the bottom surface of the second nano-posts 154a is in contact with the top surface of the first nano-posts 152a. In this case, the second nano-posts 154a may be laterally shifted relative to the first nano-posts 152a in correspondence with a chief ray angle (CRA) of incident light. For example, the second nano-posts 154a located in the center of the pixel region 100 may be located such that central axes of the second nano-posts 154a can coincide with central axes of the first nano-posts 152a as illustrated in FIG. 2, and the second nano-posts 154a located in the edge region of the pixel region 100 may be located such that central axes of the second nano-posts 154a can be shifted from the central axes of the first nano-posts 152a in response to the chief ray angle (CRA) in the corresponding area as illustrated in FIG. 3.

The stacked nano-posts (152a, 154a) may have the same shape and dimensions. For example, the stacked nano-posts (152a, 154a) may be formed in a pillar shape having the same diameter and height.

The stacked nano-posts (152a, 154a) may be arranged in a pattern that separates incident light by color and allows the separated light to be focused on the unit pixels of the corresponding color. For example, when the color filters of the unit pixels are arranged in a Bayer pattern, the nano-posts (152a, 154a) may be arranged to have a refractive index distribution capable of forming a phase profile that separates incident light by wavelengths of red, green, and blue and allowing the separated light to be focused on the unit pixels of the corresponding color. The above-described refractive index distribution may be formed by the shape and arrangement of the nano-posts (152a, 154a), and may be obtained by a difference in refractive index between the nano-posts (152a, 154a) and the air layers (152b, 154c) (e.g., material surrounding the nano-posts).

The metalens layer 150 based on an embodiment may include a structure in which the plurality of nano-posts (152a, 154a) is stacked such that the nano-posts 154a of the upper layer are shifted to correspond to the CRA, thereby ameliorating deterioration of quantum efficiency (QE) caused by oblique incident light. In an embodiment, when the nano-posts (152a, 154a) are formed with a stacked structure and the nano-posts 154a of the upper layer are shifted to correspond to the CRA, quantum efficiency (QE) degradation caused by oblique incident light can be reduced more effectively as the heights of the nano-posts (152a, 154a) are reduced. The metalens layer 150 based on an embodiment may allow the air layers (152b, 154c) to be formed between the nano-posts (152a, 154a), which increases the difference in refractive index between the nano-structure and the surrounding material. This greater refractive index difference enables the relative heights of the nano-posts (152a, 154a) to be reduced compared to an example case where a material having a higher refractive index than the air layer is used as the surrounding material.

Top surfaces and side surfaces of the second nano-posts 154a may be covered by a capping layer 154b. The capping layer 154b may include a low-temperature-oxide (LTO) layer. Although the capping layer 154b is described as being separated from the second support layer 156b for convenience of description, other configurations are also possible. For example, the capping layer 154b and the second support layer 156b may be formed of the same material and may be formed together through the same deposition process. For example, the capping layer 154b covering the second nano-posts 154a may extend to the support layer 156 located under the air layer 154c to form the second support layer 156b.

The support layer 156 may be disposed between the first nano-posts 152a so that the top surfaces of the first nano-posts 152a are exposed, and may support the second metalens layer 154. In an embodiment, when the nano-posts (152a, 154a) are formed in a stacked structure and the upper nano-posts 154a are shifted to correspond to the CRA, a part of the shifted second nano-posts 154a may not be supported by the corresponding first nano-posts 152a as illustrated in FIG. 3. In this case, when the degree of shifting is large, the second nano-posts 154a may be tilted or collapsed. In an embodiment, the support layer 156 is formed under the second metalens layer 154 to support the second nano-posts 154a. For example, among the bottom surfaces of the shifted second nano-posts 154a, a portion in contact with the first nano-posts 152a may be supported by the first nano-post 152a, and the remaining portions may be supported by the support layer 156. As a result, the second nano-posts 154a may be stacked over the first nano-posts 152a to achieve a more stable connection between the layer of the second nano-posts 154a and the layer of the first nano-posts 152a.

The support layer 156 may include a first support layer 156a including a plurality of through-holes; and a second support layer 156b covering the top surface of the first support layer 156a while filling the through-holes of the first support layer 156. The second support layer 156b may include the same material as the capping layer 154b, and may be formed together with the capping layer 154b. The second support layer 156b may be formed to also cover the bottom surface of the first support layer 156a.

The support layer 156 may be formed to surround an upper portion of the first nano-posts 152a. For example, the support layer 156 may be disposed on the air layer 152b between the first nano-posts 152a such that the support layer 156 can contact an upper side surface of the first nano-posts 152a.

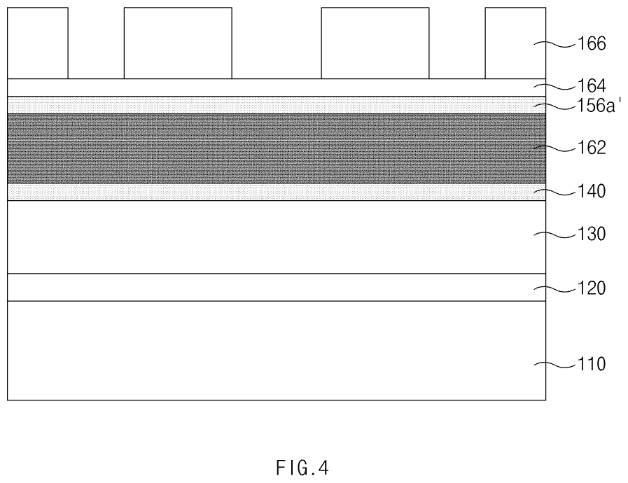

FIGS. 4 to 14 are cross-sectional views illustrating example methods for forming the structure of FIG. 2 based on some embodiments of the disclosed technology.

Referring to FIG. 4, a substrate layer 110 including photoelectric conversion elements may be formed, and a color filter layer 120 including color filters formed to correspond to the photoelectric conversion elements may be formed on the substrate layer 110.

Subsequently, an overcoating layer 130, an etch stop layer 140, a first sacrificial layer 162, a support material layer 156a′, and a bottom anti-reflective coating (BARC) layer 164 are sequentially formed on the color filter layer 120, and then a photoresist pattern 166 may be formed on the bottom anti-reflective coating (BARC) layer 164 to define an area where the first nano-posts are to be formed. In some implementations, the overcoating layer 130 may include a dielectric material having both a lower refractive index than the nano-structures (nano-posts) and a low absorption rate in the visible spectrum. The etch stop layer 140 and the support material layer 156a′ may include an ultra-low-temperature-oxide (ULTO) layer, and the first sacrificial layer 162 may include a Spin On Carbon (SOC) layer containing carbon. The bottom anti-reflective coating (BARC) layer 164 may be used as an auxiliary layer in a photolithography process for forming the photoresist pattern 166. The bottom anti-reflective coating (BARC) layer 164 may include a silicon oxynitride (SiON) layer.

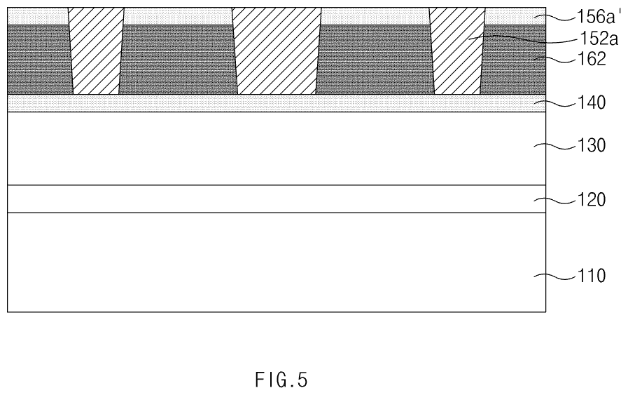

Referring to FIG. 5, the bottom anti-reflective coating (BARC) layer 164, the support material layer 156a′, and the first sacrificial layer 162 may be sequentially etched using the photoresist pattern 166 as an etch mask, thereby forming a trench in an area where the first nano-posts are to be formed.

Subsequently, after the photoresist pattern 166 and the bottom anti-reflective coating (BARC) layer 164 are removed, a high-refractive-index material is formed to fill the trench. Subsequently, any excess high-refractive-index material remaining on the support material layer 156a′ is removed through a planarization process, thereby forming the first nano-posts 152a.

The high-refractive-index material may include titanium dioxide (TiO₂), and may be formed through an atomic layer deposition (ALD) process or a spin-on coating process.

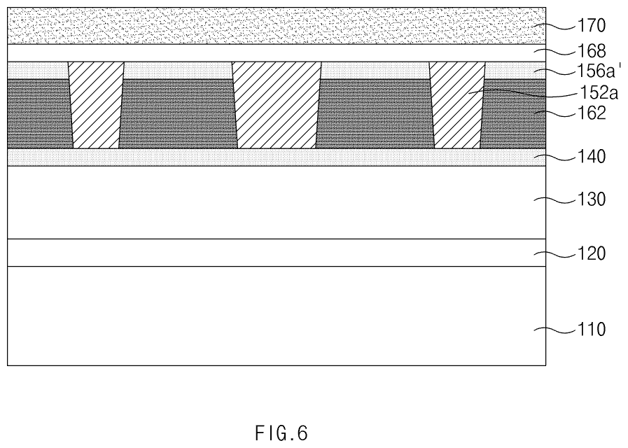

Referring to FIG. 6, a neutral layer 168 and a directed self-assembly (DSA) material layer 170 may be sequentially formed on the support material layer 156a′ and the first nano-posts 152a.

The neutral layer 168 may induce pattern formation of the DSA material layer 170. The neutral layer 168 may serve to induce phase separation of polymer blocks forming a block copolymer into block domain portions that are arranged alternately in a cylinder shape or a lamellar shape. The neutral layer 168 may operate as an orientation control layer that adjusts orientation of the polymer blocks during the phase separation process in which the polymer blocks are rearranged to form alternately arranged block domain portions.

The neutral layer 168 may be formed of a material having a similar affinity for each of the polymer block components forming the block copolymer. For example, the neutral layer 168 may include a random copolymer in which different polymer components forming the block copolymer are randomly copolymerized. When a polystyrene-polymethyl methacrylate block copolymer (PS-b-PMMA) is used as a self-aligned block copolymer, the neutral layer 168 may include a random copolymer of polystyrene and polymethyl methacrylate (PS-b-PMMA) (i.e., random PS: PMMA (PS-r-PMMA)).

The DSA material layer 170 may include a block copolymer composed of two or more types of polymer blocks having different structures that are covalently bonded to form one polymer. For example, the DSA material layer 170 may include polymethyl methacrylate (PMMA) and polystyrene (PS). The DSA material layer 170 may be coated in a homogeneous phase mixed state using a spin coating method.

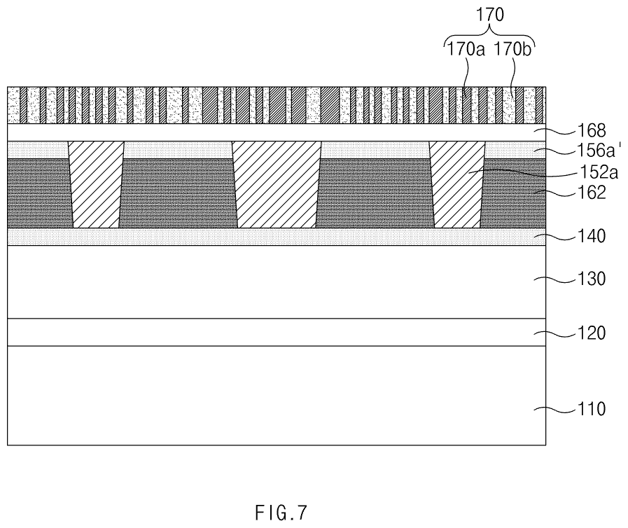

Referring to FIG. 7, DSA patterning may be performed on the DSA material layer 170. For example, an N₂ annealing process may be performed on the DSA material layer 170.

The DSA material layer 170 may be phase-separated into a first polymer block component 170a and a second polymer block component 170b by the annealing process. When the DSA material layer 170 includes a block copolymer, the DSA material layer 170 may be separated into PMMA (polymethyl methacrylate) and PS (polystyrene) by the annealing process. PMMA and PS may be self-aligned in various forms depending on a composition ratio.

The polymer block components that constitute the block copolymer may have different mixing characteristics and different solubilities due to differences in chemical structures. The polymer components may be immiscibly separated from each other while being intermixed by annealing, and may be reordered, so that the polymer components can be phase-separated from each other.

Forming a microstructure of a specific shape through directed self-assembly of the block copolymer may be affected by physical and/or chemical characteristics of each block polymer. When a block copolymer composed of two different polymers self-assembles, the self-assembled structure of the block copolymer may be formed in various structures, such as a three-dimensional (3D) cubic and double helix structure, or a two-dimensional (2D) hexagonal packed column structure and a lamellar structure, depending on a volume ratio of each polymer block that constitutes the block copolymer, the annealing temperature for phase separation, the size of a molecule of the block polymer, and other factors.

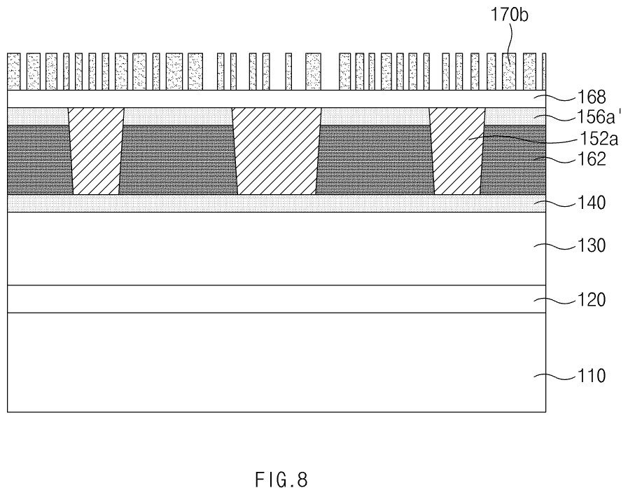

Referring to FIG. 8, the first polymer block component 170a may be selectively removed from the DSA material layer 170 separated into the first polymer block component 170a and the second polymer block component 170b.

For example, a metal-containing precursor may be injected into the DSA material layer 170 so that the metal-containing precursor can be selectively coupled (bound) to the first polymer block component 170a. The metal of the metal-containing precursor may include aluminum (Al). The metal-containing precursor may include tetramethylammonium (TMA). For example, TMA may be selectively coupled (bound) to PMMA.

By injecting such a metal-containing precursor, the metal may penetrate into the first polymer block component 170a, converting the first polymer block component 170a into a metal-containing first polymer block component. The metal-containing first polymer block component may exhibit etch selectivity over the second polymer block component 170b. The first polymer block component 170a may be selectively removed using the etch selectivity.

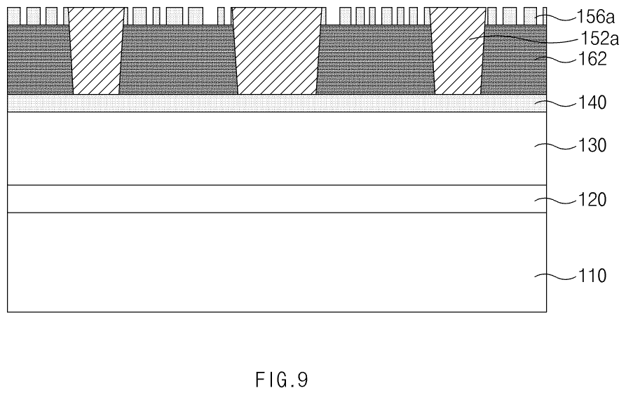

Referring to FIG. 9, the neutral layer 168 and the support material layer 156a′ are etched using a DSA pattern including the second polymer block component 170b as an etch mask, the neutral layer 168 is then removed, resulting in formation of the first support layer 156a.

When the support material layer 156a′ is etched, the first nano-posts 152a are not etched and only the support material layer 156a′ is etched using the etch selectivity, so that the first support layer 156a including the plurality of through-holes may be formed to surround the upper portion of the first nano-posts 152a.

In this case, the plurality of through-holes may allow the first sacrificial layer 162 to be exposed outside.

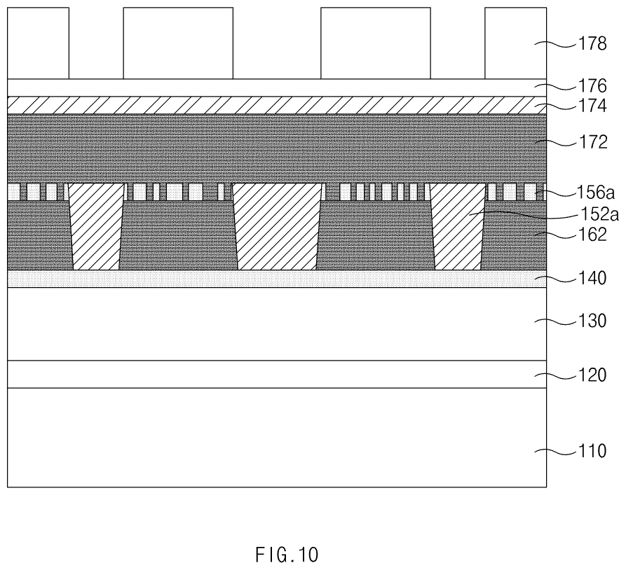

Referring to FIG. 10, a second sacrificial layer 172, a hard mask layer 174, and a bottom anti-reflective coating (BARC) layer 176 are sequentially formed on the first support layer 156a and the first nano-posts 152a, and then a photoresist pattern 178 defining areas where the second nano-posts are to be formed may be formed on the bottom anti-reflective coating (BARC) layer 176. In some implementations, the second sacrificial layer 172 may include the same material layer as the first sacrificial layer 162. For example, the second sacrificial layer 172 may include a carbon-containing SOC layer, and the hard mask layer 174 may include an ultra-low-temperature-oxide (ULTO) layer. The bottom anti-reflective coating (BARC) layer 176 may be used as an auxiliary layer in a photolithography process for forming the photoresist pattern 178, and may include a silicon oxynitride (SiON) layer.

The open regions of the photoresist pattern 178 (e.g., regions where the second nano-posts are to be formed) may be located to correspond to the CRA of incident light depending on the formation positions of the second nano-posts within the pixel region 100. For example, as illustrated in FIG. 10, the open regions of the photoresist pattern 178 are located so that central axes of the open regions coincide with central axes of the first nano-posts 152a, but the scope or spirit of the disclosed technology is not limited thereto. In the edge region of the pixel region 100, the open regions of the photoresist pattern 178 may be located to be shifted from the first nano-posts 152a.

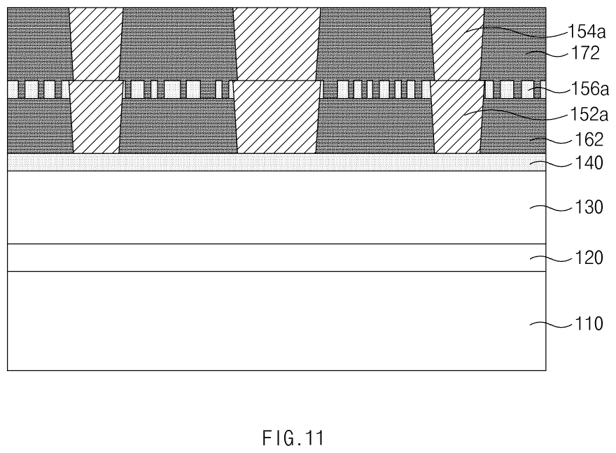

Referring to FIG. 11, the bottom anti-reflective coating (BARC) layer 176, the hard mask layer 174, and the second sacrificial layer 172 are sequentially etched using the photoresist pattern 178 as an etch mask, so that a trench can be formed in an area where second nano-posts are to be formed. The trench may be formed so that the first nano-posts 152a are exposed.

Subsequently, after the photoresist pattern 178 and the bottom anti-reflective coating (BARC) layer 176 are removed, a high-refractive-index material is formed to fill the trench, and a planarization process is performed until the second sacrificial layer 172 is exposed, so that second nano-posts 154a may be formed on the first nano-posts 152a so as to be directly connected to the first nano-posts 152a.

The high-refractive-index material may include titanium dioxide (TiO₂), and may be formed via an atomic layer deposition (ALD) process or a spin-on coating process.

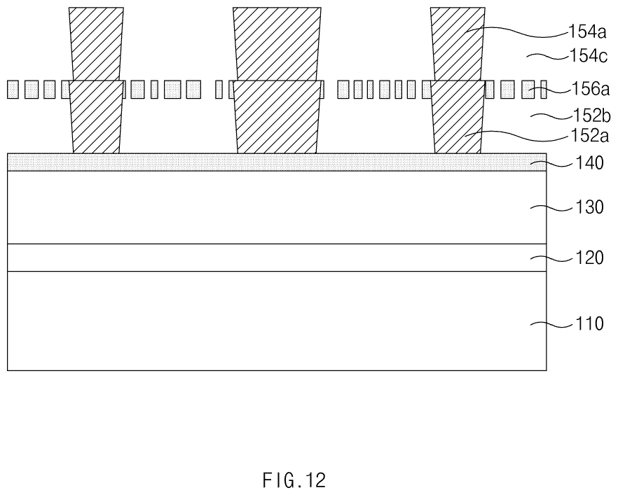

Referring to FIG. 12, the first sacrificial layer 162 and the second sacrificial layer 172 are removed through the plasma process, so that an air layer 152b may be formed in the space between the first nano-posts 152a and an air layer 154c may be formed in the space between the second nano-posts 154a.

In some implementations, the plasma process may be carried out using gas (e.g., O₂, N₂, H₂, CO, CO₂, or CH₄) including at least one of oxygen, nitrogen, or hydrogen.

For example, if the O₂ plasma process is carried out, oxygen radicals (O*) may be combined with carbons of the first and second sacrificial layers (162, 172). The oxygen radicals (O*) may be combined with carbons of the first and second sacrificial layers (162, 172), resulting in formation of CO or CO₂. As a result, the first sacrificial layer 162 and the second sacrificial layer 172 can be removed. In some implementations, the first sacrificial layer 162 formed between the first nano-posts 152a is exposed outside by a plurality of through-holes formed in the first support layer 156a, so that the first sacrificial layer 162 may be coupled to the oxygen radicals and thus may be easily removed.

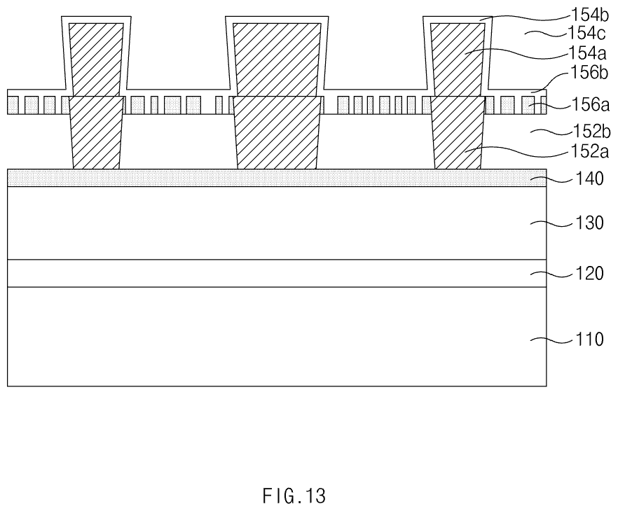

Referring to FIG. 13, a second support layer 156b and a capping layer 154b may be formed by depositing an insulating material to fill the through-holes of the first support layer 156a. For example, the second support layer 156b may be formed to cover the top surface of the first support layer 156a while filling the through-holes of the first support layer 156a, and the capping layer 154b may be formed to cover the top surfaces and side surfaces of the second nano-posts 154a.

Each of the second support layer 156b and the capping layer 154b may include a low temperature oxide (LTO) layer. In FIG. 13, the second support layer 156b and the capping layer 154b are shown separately for convenience of description, but the second support layer 156b and the capping layer 154b may be formed together through the same deposition process.

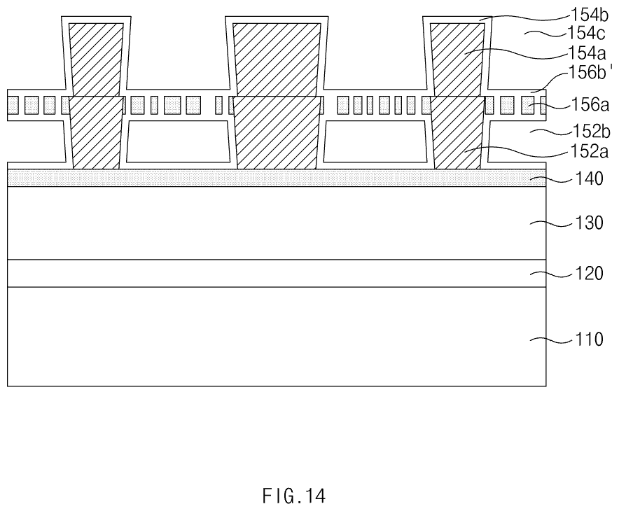

Although FIG. 13 only illustrates the example case where the second support layer 156b covers the top surface of the first support layer 156a while filling the through-holes of the first support layer 156a, other implementations are also possible. For example, the second support layer 156b′ may be formed to cover the bottom surface of the first support layer 156a, the side surfaces of the nano-posts 152a and top surface of the etch stop layer 140 as illustrated in FIG. 14.

Although the above-described embodiments provide examples where the metalens layer 150 includes the nano-structure in which two layers of nano-posts (152a, 154a) are stacked for convenience of description, other implementations are also possible. For example, three or more layers of nano-posts can be stacked.

As is apparent from the above description, the embodiments of the disclosed technology can reduce or minimize the degradation of quantum efficiency (QE) with respect to oblique incident light incident on the image sensing device to which metalenses are applied.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a semiconductor substrate including photoelectric conversion elements configured to generate photocharges by converting incident light; and
a metalens layer disposed over the semiconductor substrate, and configured to separate incident light into light components of different colors based on wavelength and to converge the separated light components onto corresponding photoelectric conversion elements,
wherein the metalens layer includes:
a first metalens layer including first nano-structures and a first air layer disposed between the first nano-structures;
a second metalens layer including second nano-structures and a second air layer disposed between the second nano-structures, wherein at least a portion of each of the second nano-structures is disposed on a corresponding first nanostructure of the first nano-structures; and
a support layer disposed over the first air layer in a space between adjacent first nano-structures of the first nano-structures.

2. The image sensing device according to claim 1, wherein:
the second nano-structures are disposed on the first nano-structures such that bottom surfaces of the second nano-structures are in contact with top surfaces of the first nano-structures.

3. The image sensing device according to claim 1, wherein:
the second nano-structures are laterally shifted relative to the first nano-structures such that central axes of the second nano-structures are shifted from central axes of the first nano-structures in correspondence with a chief ray angle (CRA) of the incident light.

4. The image sensing device according to claim 3, wherein:
a portion of a bottom surface of each of the second nano-structures is in contact with a portion of a corresponding first nano-structure of the first nano-structures, and a remaining portion of the bottom surface of each of the second nano-structures is in contact with the support layer.

5. The image sensing device according to claim 1, wherein the support layer includes:
a first support layer configured with a plurality of through-holes formed in the first support layer; and
a second support layer configured to fill the plurality of through-holes.

6. The image sensing device according to claim 5, wherein:
the second support layer is configured to cover a top surface of the first support layer.

7. The image sensing device according to claim 5, wherein:
the second support layer is configured to cover a top surface and a bottom surface of the first support layer.

8. The image sensing device according to claim 5, wherein:
the first support layer includes an ultra-low-temperature-oxide (ULTO) layer; and
the second support layer includes a low-temperature-oxide (LTO) layer.

9. The image sensing device according to claim 1, wherein:
the support layer is configured to surround upper portion of the first nano-structures such that top surfaces of the first nano-structures are exposed.

10. The image sensing device according to claim 1, wherein the second metalens layer further includes:
a capping layer configured to cover top surfaces and side surfaces of the second nano-structures.

11. The image sensing device according to claim 10, wherein:
the capping layer is configured to extend to a region below the second air layer.

12. The image sensing device according to claim 1, further comprising:
a color filter layer disposed between the semiconductor substrate and the metalens layer.

13. The image sensing device according to claim 12, further comprising:
an overcoating layer disposed over the color filter layer; and
an etch stop layer disposed between the overcoating layer and the first nano-structures.

14. An image sensing device comprising:
a semiconductor substrate including photoelectric conversion elements configured to generate photocharges by converting incident light;
a plurality of first nano-structures disposed over the semiconductor substrate;
a first air layer disposed between adjacent first nano-structures of the plurality of first nano-structures;
a support layer disposed between the adjacent first nano-structures such that at least a portion of the adjacent first nano-structures are exposed;
a plurality of second nano-structures disposed over the first nano-structures; and
a second air layer disposed between the second nano-structures.

15. The image sensing device according to claim 14, wherein:
the second nano-structures are laterally shifted relative to the first nano-structures such that central axes of the second nano-structures are shifted from central axes of the first nano-structures in correspondence with a chief ray angle (CRA) of the incident light.

16. The image sensing device according to claim 15, wherein:
a portion of a bottom surface of each of the second nano-structures is in contact with a portion of a corresponding first nano-structure of the first nano-structures, and a remaining portion of the bottom surface of each of the second nano-structures is in contact with the support layer.

17. The image sensing device according to claim 14, wherein the support layer includes:
a first support layer configured with a plurality of through-holes formed in the first support layer; and
a second support layer configured to fill the plurality of through-holes.

18. The image sensing device according to claim 17, wherein:
the second support layer is configured to cover a top surface of the first support layer.

19. The image sensing device according to claim 17, wherein:
the second support layer is configured to cover a top surface and a bottom surface of the first support layer.

20. The image sensing device according to claim 14, further comprising:
a capping layer configured to cover top surfaces and side surfaces of the second nano-structures.
